(19) United States
(12) Patent Application Publication
(10) Pub. No.: US 2013/0344688 A1
(43) Pub. Date: Dec. 26, 2013

(54) Atomic Layer Deposition with Rapid Thermal Treatment

(71) Applicant: Zhiyuan Ye, San Jose, CA (US)

(72) Inventor: Zhiyuan Ye, San Jose, CA (US)

(21) Appl. No.: 13/803,020

(22) Filed: Mar. 14, 2013

Related U.S. Application Data
(60) Provisional application No. 61/662,335, filed on Jun. 20, 2012.

(51) Int. Cl. H01L 21/02

(52) U.S. Cl. CPC H01L 21/02636
USPC 438/486; 438/478

(57) ABSTRACT

Provided are methods and apparatus for atomic layer deposition of a film with rapid thermal treatment. Methods described can be used to convert an amorphous film to form an epitaxial film with rapid thermal treatment or to selectively deposit a film on a portion of a substrate. A thermal element in the apparatus is capable of globally or locally changing the temperature of the amorphous film or a portion of the amorphous film by temporarily rapidly raising the temperature of the amorphous film converting the film to an epitaxial film.

### CROSS-REFERENCE TO RELATED APPLICATIONS

This application claims priority to U.S. Provisional Application No. 61/662,335, filed Jun. 20, 2012.

### BACKGROUND

Embodiments of the invention generally relate to an apparatus and a method for depositing materials and forming films on a substrate. More specifically, embodiments of the invention are directed to atomic layer deposition chambers capable of spiking the temperature of the film.

In the field of semiconductor processing, flat-panel display processing or other electronic device processing, vapor deposition processes have played an important role in depositing materials on substrates. As the geometries of electronic devices continue to shrink and the density of devices continues to increase, the size and aspect ratio of the features are becoming more aggressive, e.g., feature sizes of 0.07 μm and aspect ratios of 10 or greater. Accordingly, conformal deposition of materials to form these devices is becoming increasingly important.

During an atomic layer deposition (ALD) process, reactant gases are introduced into a process chamber containing a substrate. Generally, a region of a substrate is contacted with a first reactant which is adsorbed onto the substrate surface. The substrate is then contacted with a second reactant which reacts with the first reactant to form a deposited material. A purge gas may be introduced between the delivery of each reactant gas to ensure that the only reactions that occur are on the substrate surface.

Atomic layer deposition has been widely used for the deposition of high-k dielectrics and metal liners. However, using ALD for epitaxy is a challenge because the high temperatures generally required for good quality epitaxial growth may be too high for effective ALD precursors. Current epitaxial technologies on the other hand face the challenge of good conformity, low thermal budget and selectivity etch. Therefore, there is an ongoing need in the art for methods of depositing an epitaxial film with good conformity and low thermal budget.

### SUMMARY

One or more embodiments of the invention are directed to methods of forming a film on a substrate. The substrate, or portion of the substrate, is exposed to a first reactive gas at a first temperature to absorb the first reactive gas to the substrate, or a portion of the substrate. The temperature of the absorbed reactive gas is rapidly raised to a second temperature greater than the first temperature to form a film.

Some embodiments further comprise exposing the absorbed reactive gas on the substrate, or portion of the substrate, to a second reactive gas which is different from the first reactive gas. In one or more embodiments, the substrate, or portion of the substrate, is exposed to the second reactive gas before the temperature of the absorbed reactive gas is rapidly raised. In some embodiments, the substrate, or portion of the substrate, is exposed to the second reactive gas before the temperature of the absorbed reactive gas is rapidly raised. In one or more embodiments, the substrate, or portion of the substrate, is exposed to the second reactive gas after the temperature of the absorbed reactive gas after the temperature of the absorbed reactive gas is rapidly raised. Some embodiments further comprise rapidly raising the temperature of the film after each of absorbing the first reactive gas to the substrate and exposure to the second reactive gas.

In some embodiments, the first temperature is up to about 400° C. and the second temperature is greater than about 600° C. In one or more embodiments, the temperature is raised at a rate greater than about 50° C./sec.

In one or more embodiments, the first reactive gas is selectively absorbed onto a first portion of the substrate at the first temperature over a second portion of the substrate.

In some embodiments, the film formed is one or more of an epitaxial film, a dielectric, a high-k dielectric and a metal film.

One or more embodiments further comprise positioning the substrate in a processing chamber on a substrate support ring, the processing chamber comprising a lamphead facing one or more of a front side of the substrate and a back side of the substrate, and one or more of a showerhead and a gas injector in a sidewall of the processing chamber, the showerhead being positioned on an opposite side of the substrate from the lamphead.

Additional embodiments of the invention are directed to methods of forming an epitaxial film on a substrate. The substrate, or portion of the substrate, is exposed to a first reactive gas at a first temperature to form an amorphous film on a surface, or portion of a surface, of the substrate. The temperature of the amorphous film is rapidly raised to a second temperature greater than the first temperature to form an epitaxial film.

In some embodiments, the temperature of the amorphous film is raised at a rate greater than about 50° C./sec.

One or more embodiments further comprise exposing the substrate, or portion of the substrate, to a second reactive gas different from the first reactive gas to form the amorphous film.

In some embodiments, the substrate, or portion of the substrate, is exposed to the second reactive gas after removing the first reactive gas. In one or more embodiments, the substrate, or portion of the substrate, is exposed to the second reactive gas at the same time as the first reactive gas.

In some embodiments, the substrate, or portion of the substrate, is exposed to both the first reactive gas and the second reactive gas at the same time. Each of the first reactive gas and the second reactive gas are delivered to the substrate surface separately and removed from the substrate surface without mixing.

In one or more embodiments, the substrate is exposed sequentially to the first reactive gas at the first temperature, the second reactive gas and then rapidly heated to the second temperature to form the epitaxial film.

In some embodiments, the first temperature is up to about 400° C. In one or more embodiments, the second temperature is greater than about 600° C. In some embodiments, rapidly raising the temperature of the amorphous film occurs over a time period up to about 60 seconds.

In some embodiments, the amorphous film formed is up to about one monolayer thick before rapidly raising the temperature to form the epitaxial film. One or more embodiments further comprise sequentially forming an amorphous film on the epitaxial film, the amorphous film having a thickness up to about one monolayer thick, followed by rapidly raising the temperature to form the epitaxial film. In some embodiments, exposure to the first precursor followed by the second precursor results in one amorphous film up to about one monolayer thick before rapidly raising the temperature to form the epitaxial film.

Some embodiments further comprise rotating the substrate during formation of the amorphous film and the epitaxial film.

In one or more embodiments, the temperature of the amorphous film is rapidly raised by one or more of UV lamps, lasers and exposure to plasma.

In some embodiments, additional processing is performed one or more of before and after the formation of the epitaxial film on the substrate without exposing the substrate to the ambient environment.

In one or more embodiments, the first reactive gas is selectively absorbed onto a first portion of the substrate at the first temperature over a second portion of the substrate.

Further embodiments of the invention are directed to methods of forming an epitaxial film on a substrate surface, or portion of a substrate surface. The substrate is positioned on a substrate support. The substrate support holding the substrate is laterally moved beneath a gas distribution plate comprising a plurality of elongate gas ports including a first outlet A to deliver a first reactive gas and a second outlet B to deliver a second reactive gas. The first reactive gas is delivered to the substrate surface, or portion of the substrate surface. The second reactive gas is delivered to the substrate surface, or portion of the substrate surface, to form an amorphous film on the substrate surface. The local temperature of at least a portion of the amorphous film is rapidly changed to convert the amorphous film to an epitaxial film. In some embodiments, the amorphous film temperature is rapidly changed by one or more of radiative heating and resistive heating.

### BRIEF DESCRIPTION OF THE DRAWINGS

So that the manner in which the above recited features of the invention are attained and can be understood in detail, a more particular description of the invention, briefly summarized above, may be had by reference to the embodiments thereof which are illustrated in the appended drawings. It is to be noted, however, that the appended drawings illustrate only typical embodiments of this invention and are therefore not to be considered limiting of its scope, for the invention may admit to other equally effective embodiments.

FIG. 1 shows a schematic cross-sectional view of an atomic layer deposition chamber according to one or more embodiments of the invention;

FIG. 2 shows a susceptor in accordance with one or more embodiments of the invention;

FIG. 3 shows a schematic view of a processing chamber with a gas distribution plate and a thermal element in accordance with one or more embodiments of the invention;

FIG. 4 shows a partial cross-sectional side view of an atomic layer deposition chamber in accordance with one or more embodiments of the invention;

FIG. 5 shows a partial cross-sectional side view of an atomic layer deposition chamber in accordance with one or more embodiments of the invention;

FIG. 6 shows a partial cross-sectional side view of an atomic layer deposition chamber in accordance with one or more embodiments of the invention;

FIG. 7 shows a partial cross-sectional side view of an atomic layer deposition chamber in accordance with one or more embodiments of the invention;

FIG. 8 shows a partial cross-sectional side view of an atomic layer deposition chamber in accordance with one or more embodiments of the invention; and

FIG. 9 shows a partial cross-sectional side view of an atomic layer deposition chamber in accordance with one or more embodiments of the invention;

FIG. 10 shows a partial cross-sectional side view of an atomic layer deposition chamber in accordance with one or more embodiments of the invention;

FIG. 11 shows a partial cross-sectional side view of the lid assembly from FIG. 10;

FIG. 12 shows a partial cross-sectional side view of the support assembly from FIG. 10;

FIG. 13 shows a schematic view of a deposition system in accordance with one or more embodiment of the invention;

FIG. 14 shows a schematic view of a deposition system in accordance with one or more embodiment of the invention;

FIG. 15 shows a schematic view of a deposition system in accordance with one or more embodiment of the invention; and

FIG. 16 shows a schematic view of a cluster tool in accordance with one or more embodiments of the invention.

### DETAILED DESCRIPTION

Embodiments of the invention are directed to atomic layer deposition apparatus and methods for depositing a film by atomic layer deposition. For example, a high-k dielectric film or an epitaxial film can be deposited. One or more embodiments of the invention are directed to atomic layer deposition apparatuses (also called cyclical deposition) incorporating rapid thermal processing treatment.

According to one or more embodiments, atomic layer deposition (ALD) with rapid thermal treatment for crystal growth involve some or all of the following steps. In some embodiments, ALD style of precursors absorption on exposed epitaxy surface of the substrate and pumping out of the precursor. This could be done at optimal temperature for the precursor (typically at relatively low temperatures of less than about 400° C.). ALD of a second precursor, in case a compound material is desired, or multiple precursor reactions needed, for example, III-V semiconductors. RTP treatment to spike the wafer temperature to a high level to promote good quality crystal growth (as a cure step). UV lamps, for example, could be used to assist the reactions. The wafer temperature is then returned back to ALD temperature for following cycles.

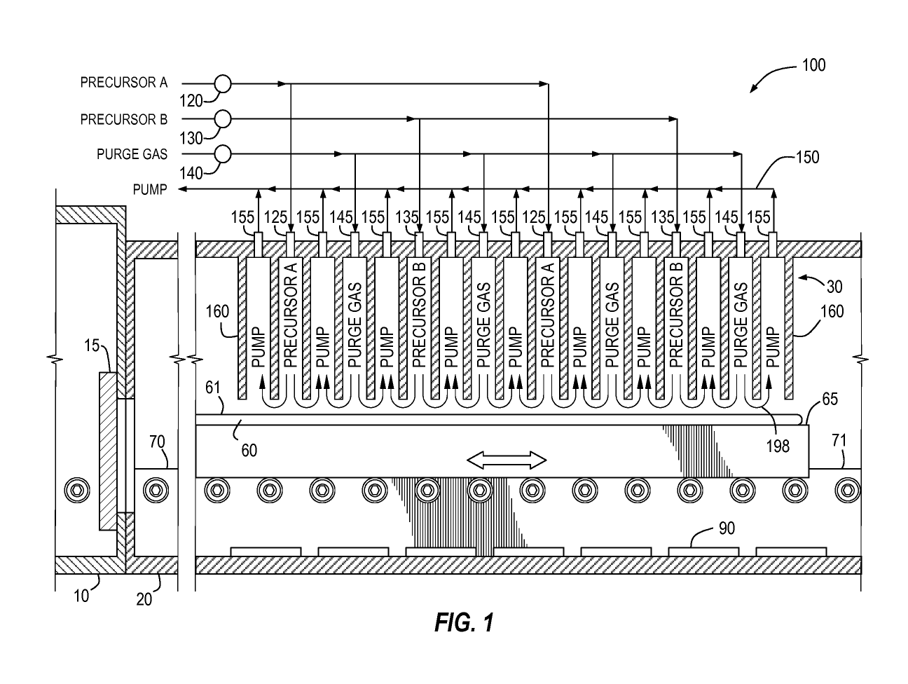

As used in this specification and the appended claims, the term “substrate” and “wafer” are used interchangeably, both referring to a surface, or portion of a surface, upon which a process acts. It will also be understood by those skilled in the art that reference to a substrate can also refer to only a portion of the substrate, unless the context clearly indicates otherwise. For example, in spatially separated ALD, described with respect to FIG. 1, each precursor is delivered to the substrate, but any individual precursor stream, at any given time, is only delivered to a portion of the substrate.

FIG. 1 is a schematic cross-sectional view of an atomic layer deposition system or system 100 in accordance with one or more embodiments of the invention. The system 100 includes a load lock chamber 10 and a processing chamber 20. The processing chamber 20 is generally a sealable enclosure, which is operated under vacuum, or at least low pressure. The processing chamber 20 is isolated from the load lock chamber 10 by an isolation valve 15. The isolation valve 15 seals the processing chamber 20 from the load lock chamber 10 in a closed position and allows a substrate 60 to be transferred from the load lock chamber 10 through the valve to the processing chamber 20 and vice versa in an open position.

The system 100 includes a gas distribution plate 30 capable of distributing one or more gases across a substrate 60. The gas distribution plate 30 can be any suitable distribution plate known to those skilled in the art, and specific gas distribution plates described should not be taken as limiting the scope of the invention. The output face of the gas distribution plate 30 faces the first surface 61 of the substrate 60.

Substrates for use with the embodiments of the invention can be any suitable substrate. In some embodiments, the substrate is a rigid, discrete, generally planar substrate. As used in this specification and the appended claims, the term “discrete” when referring to a substrate means that the substrate has a fixed dimension. The substrate of one or more embodiments is a semiconductor substrate, such as a 200 mm or 300 mm diameter silicon substrate. In some embodiments, the substrate is one or more of silicon, silicon germanium, gallium arsenide, gallium nitride, germanium, gallium phosphide, indium phosphide, sapphire and silicon carbide.

The gas distribution plate 30 comprises a plurality of gas ports to transmit one or more gas streams to the substrate 60 and a plurality of vacuum ports disposed between each gas port to transmit the gas streams out of the processing chamber 20. In the embodiment of FIG. 1, the gas distribution plate 30 comprises a first precursor injector 120, a second precursor injector 130 and a purge gas injector 140. The injectors 120, 130, 140 may be controlled by a system computer (not shown), such as a mainframe, or by a chamber-specific controller, such as a programmable logic controller. The precursor injector 120 injects a continuous (or pulse) stream of a reactive precursor of compound A into the processing chamber 20 through a plurality of gas ports 125. The precursor injector 130 injects a continuous (or pulse) stream of a reactive precursor of compound B into the processing chamber 20 through a plurality of gas ports 135. The purge gas injector 140 injects a continuous (or pulse) stream of a non-reactive or purge gas into the processing chamber 20 through a plurality of gas ports 145. The purge gas removes reactive material and reactive by-products from the processing chamber 20. The purge gas is typically an inert gas, such as, nitrogen, argon and helium. Gas ports 145 are disposed in between gas ports 125 and gas ports 135 so as to separate the precursor of compound A from the precursor of compound B, thereby avoiding cross-contamination between the precursors.

In another aspect, a remote plasma source (not shown) may be connected to the precursor injector 120 and the precursor injector 130 prior to injecting the precursors into the processing chamber 20. The plasma of reactive species may be generated by applying an electric field to a compound within the remote plasma source. Any power source that is capable of activating the intended compounds may be used. For example, power sources using DC, radio frequency (RF), and microwave (MW) based discharge techniques may be used. If an RF power source is used, it can be either capacitively or inductively coupled. The activation may also be generated by a thermally based technique, a gas breakdown technique, a high energy light source (e.g., UV energy), or exposure to an x-ray source. Exemplary remote plasma sources are available from vendors such as MKS Instruments, Inc. and Advanced Energy Industries, Inc.

The system 100 further includes a pumping system 150 connected to the processing chamber 20. The pumping system 150 is generally configured to evacuate the gas streams out of the processing chamber 20 through one or more vacuum ports 155. The vacuum ports 155 are disposed between each gas port so as to evacuate the gas streams out of the processing chamber 20 after the gas streams react with the substrate surface and to further limit cross-contamination between the precursors.

The system 100 includes a plurality of partitions 160 disposed on the processing chamber 20 between each port. A lower portion of each partition extends close to the first surface 61 of substrate 60, for example, about 0.5 mm or greater from the first surface 61. In this manner, the lower portions of the partitions 160 are separated from the substrate surface by a distance sufficient to allow the gas streams to flow around the lower portions toward the vacuum ports 155 after the gas streams react with the substrate surface. Arrows 198 indicate the direction of the gas streams. Since the partitions 160 operate as a physical barrier to the gas streams, they also limit cross-contamination between the precursors. The arrangement shown is merely illustrative and should not be taken as limiting the scope of the invention. It will be understood by those skilled in the art that the gas distribution system shown is merely one possible distribution system and the other types of showerheads and gas distribution plates may be employed.

Atomic layer deposition systems of this sort (i.e., where multiple gases are separately flowed to the substrate at the same time) may be referred to as spatial ALD. In operation, a substrate 60 is delivered (e.g., by a robot) to the load lock chamber 10 and is placed on a shuttle 65. After the isolation valve 15 is opened, the shuttle 65 is moved along the track 71. Once the shuttle 65 enters in the processing chamber 20, the isolation valve 15 closes, sealing the processing chamber 20. The shuttle 65 is then moved through the processing chamber 20 for processing. In one embodiment, the shuttle 65 is moved in a linear path through the chamber.

As the substrate 60 moves through the processing chamber 20, the first surface 61 of substrate 60 is repeatedly exposed to the precursor of compound A coming from gas ports 125 and the precursor of compound B coming from gas ports 135, with the purge gas coming from gas ports 145 in between. Injection of the purge gas is designed to remove unreacted material from the previous precursor prior to exposing the substrate surface 110 to the next precursor. After each exposure to the various gas streams (e.g., the precursors or the purge gas), the gas streams are evacuated through the vacuum ports 155 by the pumping system 150. Since a vacuum port may be disposed on both sides of each gas port, the gas streams are evacuated through the vacuum ports 155 on both sides. Thus, the gas streams flow from the respective gas ports vertically downward toward the first surface 61 of the substrate 60, across the substrate surface 110 and around the lower portions of the partitions 160, and finally upward toward the vacuum ports 155. In this manner, each gas may be uniformly distributed across the substrate surface 110. Arrows 198 indicate the direction of the gas flow. Substrate 60 may also be rotated while being exposed to the various gas streams. Rotation of the substrate may be useful in preventing the formation of strips in the formed layers. Rotation of the substrate can be continuous or in discrete steps.

Sufficient space is generally provided at the end of the processing chamber 20 so as to ensure complete exposure by the last gas port in the processing chamber 20 and other processing equipment (see FIG. 3). Once the substrate 60 reaches the end of the processing chamber 20 (i.e., the first surface 61 has completely been exposed to every gas port in the processing chamber 20), the substrate 60 returns back in a direction toward the load lock chamber 10. As the substrate 60 moves back toward the load lock chamber 10, the substrate surface may be exposed again to the precursor of compound A, the purge gas, and the precursor of compound B, in reverse order from the first exposure.

The extent to which the substrate surface 110 is exposed to each gas may be determined by, for example, the flow rates of each gas coming out of the gas port and the rate of movement of the substrate 60. In one embodiment, the flow rates of each gas are controlled so as not to remove adsorbed precursors from the substrate surface 110. The width between each partition, the number of gas ports disposed on the processing chamber 20, and the number of times the substrate is passed back and forth may also determine the extent to which the substrate surface 110 is exposed to the various gases. Consequently, the quantity and quality of a deposited film may be optimized by varying the above-referenced factors.

In another embodiment, the system 100 may include a precursor injector 120 and a precursor injector 130, without a purge gas injector 140. Consequently, as the substrate 60 moves through the processing chamber 20, the substrate surface 110 will be alternately exposed to the precursor of compound A and the precursor of compound B, without being exposed to purge gas in between.

The embodiment shown in FIG. 1 has the gas distribution plate 30 above the substrate. While the embodiments have been described and shown with respect to this upright orientation, it will be understood that the inverted orientation is also possible. In that situation, the first surface 61 of the substrate 60 will face downward, while the gas flows toward the substrate will be directed upward.

In yet another embodiment, the system 100 may process a plurality of substrates. In such an embodiment, the system 100 may include a second load lock chamber (disposed at an opposite end of the load lock chamber 10) and a plurality of substrates 60. The substrates 60 may be delivered to the load lock chamber 10 and retrieved from the second load lock chamber.

In some embodiments, the shuttle 65 is a susceptor 66 for carrying the substrate 60. Generally, the susceptor 66 is a carrier which helps to form a uniform temperature across the substrate. The susceptor 66 is movable in both directions (left-to-right and right-to-left, relative to the arrangement of FIG. 1) between the load lock chamber 10 and the processing chamber 20. The susceptor 66 has a top surface 67 for carrying the substrate 60. The susceptor 66 may be a heated susceptor so that the substrate 60 may be heated for processing. As an example, the susceptor 66 may be heated by radiant heat lamps 90, a heating plate, resistive coils, or other heating devices, disposed underneath the susceptor 66.

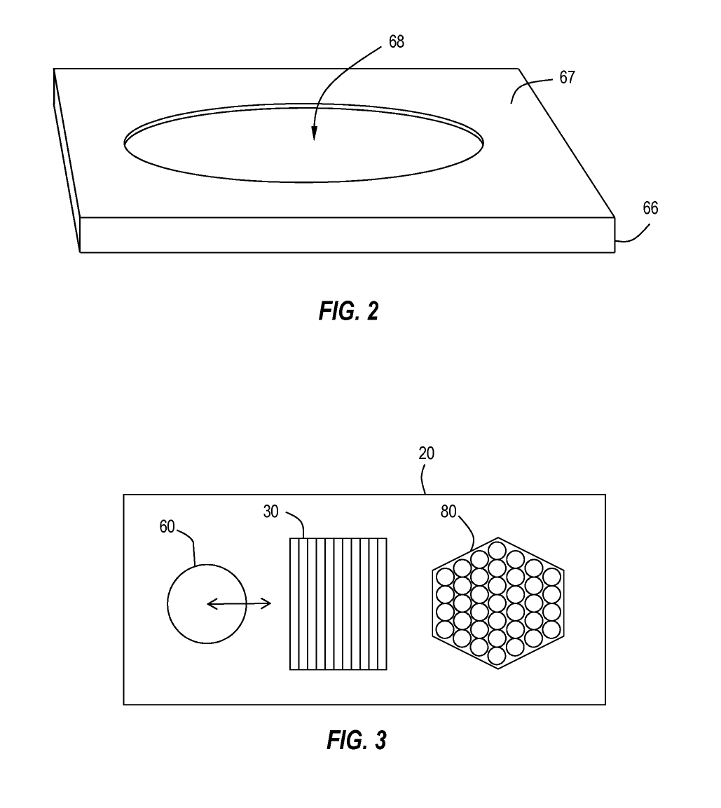

In still another embodiment, the top surface 67 of the susceptor 66 includes a recess 68 to accept the substrate 60, as shown in FIG. 2. The susceptor 66 is generally thicker than the thickness of the substrate so that there is susceptor material beneath the substrate. In some embodiments, the recess 68 is sized such that when the substrate 60 is disposed inside the recess 68, the first surface 61 of substrate 60 is level with the top surface 67 of the susceptor 66. Stated differently, the recess 68 of some embodiments is sized such that when a substrate 60 is disposed therein, the first surface 61 of the substrate 60 does not protrude above the top surface 67 of the susceptor 66.

In some embodiments, the substrate is thermally isolated from the carrier to minimize heat losses. This can be done by any suitable means, including but not limited to, minimizing the surface contact area and using low thermal conductance materials.

Substrates have an inherent thermal budget which is limited based on previous processing done on the substrate and any planned or potential future processing. Therefore, it is useful to limit the exposure of the substrate to large prolonged temperature variations to avoid exceeding this thermal budget, thereby damaging the previous processing.

FIG. 3 shows an embodiment of a processing system 20 with a substrate 60, a gas distribution plate 30 and a rapid thermal processing device, also referred to as a thermal element 80. The gas distribution plate 30 can be any suitable gas distribution plate including the spatial ALD gas distribution plate of FIG. 1 or a traditional vortex lid or showerhead. In use, the substrate 60 moves adjacent the gas distribution plate 30 for ALD processing. After the desired number of atomic layers have been deposited, the substrate 60 is moved adjacent the thermal element 80 where the amorphous film deposited on the substrate is thermally processed to create an epitaxial layer, as will be explained further below. The chamber 20 of FIG. 3 shows minimal components in a broad description and should not be taken as limiting the scope of the invention. The chamber 20 may include other components including, but not limited to, partitions to act as separations between the gas distribution plate 30 and the thermal element 80, gas inlets and exhaust ports.

In some embodiments, the gas distribution plate 30 includes at least one thermal element 80 to cause a local change in temperature at the surface of a portion of the substrate 60. The local change in temperature affects primarily a portion of the surface of the substrate 60 without affecting the bulk temperature of the substrate.

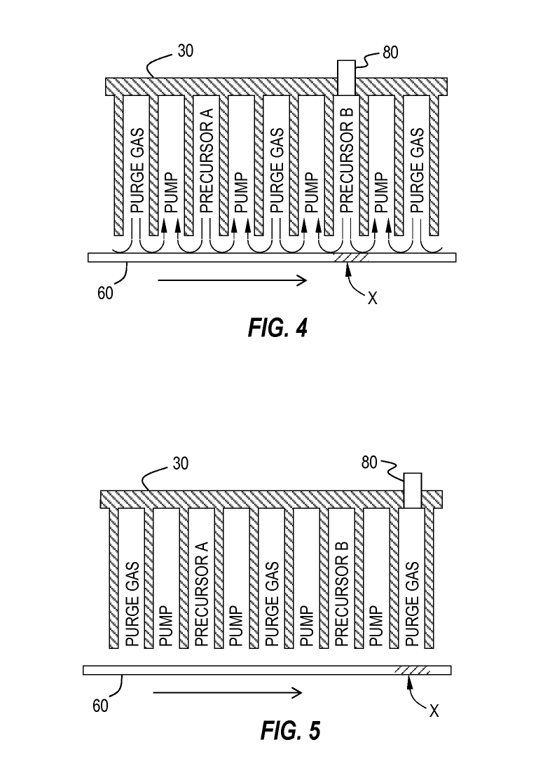

Referring to FIG. 4, in operation, the substrate 60 moves relative to the gas ports of the gas distribution plate 30, as shown by the arrow. The processing chamber 20, in this embodiment, is held at a temperature which is suitable for efficient reaction of precursor A with the substrate 60, or layer on the substrate 60, but is too low for efficient reaction of precursor B. Region X moves past gas ports with purge gases, vacuum ports and a first precursor A port, where the surface of the substrate 60 reacts with the first precursor A. Because the processing chamber 20 is held at a temperature suitable for the precursor A reaction, as the substrate 60 moves to precursor B, the region X is affected by the thermal element 80 and the local temperature of region X is increased. In some embodiments, the local temperature of region X is increased to a temperature which reaction of precursor B is favorable.

It will be understood by those skilled in the art that, as used and described herein, region X is an artificially fixed point or region of the substrate. In actual use in a spatial ALD process, the region X would be, literally, a moving target, as the substrate is moving adjacent the gas distribution plate 30. For descriptive purposes, the region X shown is at a fixed point during processing of the substrate.

In some embodiments, the region X, which is also referred to as a portion of the substrate is limited in size. In some embodiments, the portion of the substrate effected by any individual thermal element is less than about 20% of the area of the substrate. In various embodiments, the portion of the substrate effected by any individual thermal element is less than about 15%, 10%, 5% or 2% of the area of the substrate.

The thermal element 80 can any suitable temperature altering device and can be positioned in many locations. Suitable examples of thermal elements 80 include, but are not limited to, radiative heaters (e.g., lamps and lasers), conductive heaters and resistive heaters. For example, the thermal element 80 shown in FIG. 3 is representative of a hexagonal array of individual UV lamps. Suitable thermal elements 80 are capable of rapidly elevating the temperature of the substrate, or the film on the substrate, to temperatures up to about 1300° C. (or higher) in less than about one minute.

Rapidly elevated temperatures can result in various undesirable side effects and reactions. For example, many compounds decompose rapidly at high temperatures. This can be avoided by careful selection of the temperatures used in the reactions and the spike conditions. For example, during heating, some protective gases environment could exist, for example, some group V gases in III-V reaction to prevent decomposition of compound.

FIGS. 4-6 show various thermal element 80 placements and types. It should be understood that these examples are merely illustrative of some embodiments of the invention are should not be taken as limiting the scope of the invention. In some embodiments, the thermal element 80 is positioned within at least one elongate gas port. Embodiments of this variety are shown in FIGS. 4-5. In FIG. 4, the thermal element 80 is a radiative heater (e.g., lamp or laser) positioned at an entrance to the gas port. The radiative heater can be used to directly heat region X of the substrate 60 as it passes adjacent to the gas port containing the radiative heater. Here, the region X of the substrate is heated and changed when the region X is adjacent about gas port B.

It will be understood by those skilled in the art that there can be more than one thermal element 80 in any given gas distribution plate 30. An example of this would be a gas distribution plate 30 with two repeating units of precursor A and precursor B. If the reaction temperature of precursor B is higher than precursor A, a thermal element may be placed within, or around/near each of the precursor B gas ports.

In one or more embodiments, the radiative heater is a laser which is directed along the gas port toward the surface of the substrate 60. It can be seen from FIG. 4 that as region X passes the thermal element, the elevated temperature remains for a period of time. The amount of time that the temperature remains elevated for that region depends on a number of factors. Accordingly, in some embodiments, the radiative heater is positioned at one of the vacuum port or purge gas ports before precursor B gas port. In these embodiments, region X maintains the residual heat long enough to enhance reaction of precursor B. In these embodiments, the region X is heated and the temperature changed in a region extending from about gas port A to about gas port B.

FIG. 5 shows an alternate embodiment in which the radiative heater is placed within a purge gas port. The placement of this radiative heater is after the region X encounters precursor A and precursor B. The heater of this embodiments heats the substrate, or film on the substrate, or portion of the substrate or film on the substrate in region X.

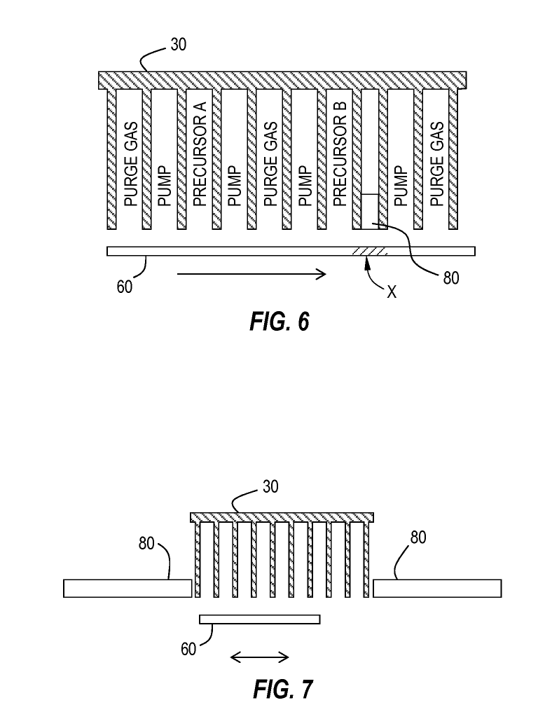

FIG. 6 shows another embodiment in which the thermal element 80 is positioned at a front face of the gas distribution plate 30. The thermal element 80 is shown in a portion of the gas distribution plate which is between two gas ports. The size of this thermal element can be adjusted as necessary to minimize the gap between the adjacent gas ports. In one or more embodiments, the thermal element has a size that is about equal to the width of the partitions 160. The thermal element 80 of these embodiments can be any suitable thermal element. In some embodiments, the thermal element 80 positioned at a front face of the gas distribution plate to directly heat the portion, region X, of the substrate 60. In some embodiments, the thermal element 80 is positioned on either side of a gas port. These embodiments are particularly suitable for use with reciprocal motion processing where the substrate move back and forth adjacent the gas distribution plate 30.

The thermal element 80 may be positioned before and/or after the gas distribution plate 30, as shown in FIG. 3. These embodiments are suitable for both reciprocal processing chambers in which the substrates moves back and forth adjacent the gas distribution plate, and in continuous (carousel or conveyer) architectures. In some embodiments the thermal element 80 is a heat lamp. In the embodiment shown in FIG. 7, there are two thermal elements 80, one on either side of the gas distribution plate, so that in reciprocal type processing, the substrate 60 is heated in both processing directions.

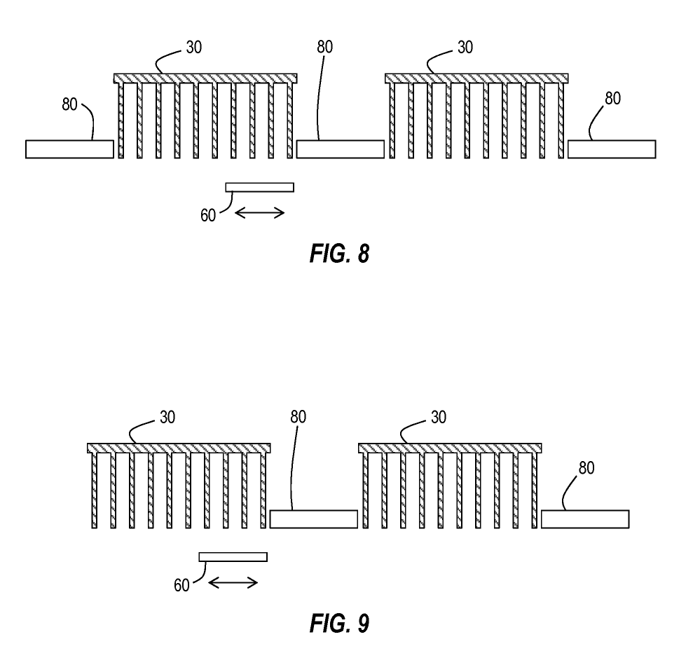

FIG. 8 shows another embodiment of the invention in which there are two gas distribution plates 30 with thermal elements 80 before, after and between each of the gas distribution plates 30. This embodiment is of particular use with reciprocal processing chambers as it allows for more layers to be deposited in a single cycle (one pass back and forth). Because there is a thermal element 80 at the beginning and end of the gas distribution plates 30, the substrate 60 is affected by the thermal element 80 before passing the gas distribution plate 30 in either the forward (e.g., left-to-right) or reverse (e.g., right-to-left) movement. It will be understood by those skilled in the art that the processing chamber 20 can have any number of gas distribution plates 30 with thermal elements 80 before and/or after each of the gas distribution plates 30 and the invention should not be limited to the embodiments shown.

FIG. 9 shows another embodiment similar to that of FIG. 8 with the thermal element 80 after each gas distribution plate 30. Embodiments of this sort are of particular use with continuous processing, rather than reciprocal processing. For example, the processing chamber 20 may contain any number of gas distribution plates 30 with a thermal element 80 before each plate.

In some embodiments, the thermal element 80 is a gas distribution plate, or portion of a gas distribution plate, to direct a stream of gas, which has been heated or cooled, toward the surface of the substrate. Additionally, the gas distribution plate can be heated or cooled so that proximity to the substrate can cause a change in the substrate surface temperature. For example, in a continuous processing environment, the processing chamber may have several gas distribution plates, or a single plate with a large number of gas ports. One or more of the gas distribution plates (where there are more than one) or some of the gas ports can provide heated or cooled gas or radiant energy.

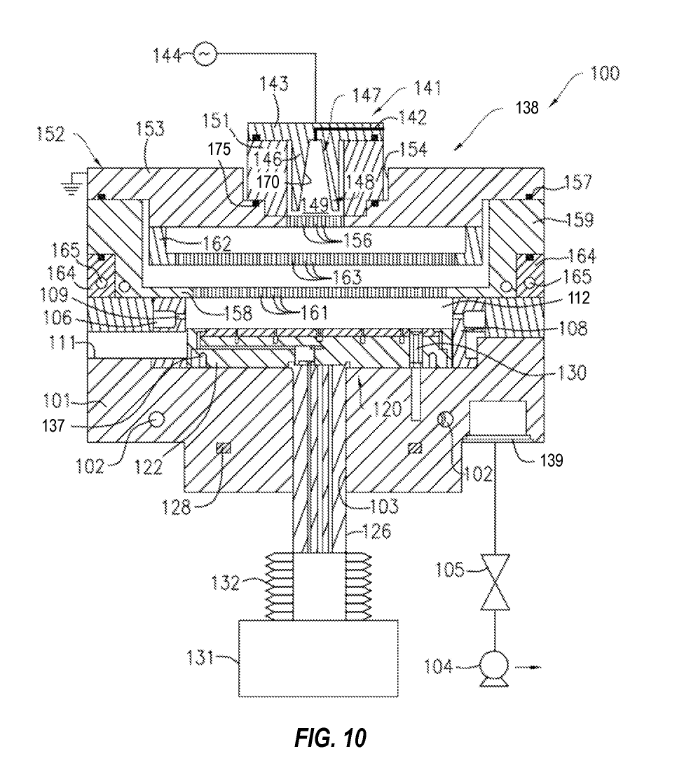

FIG. 10 is a partial cross sectional view showing a processing chamber 100 suitable for use with time-domain type atomic layer deposition. As used in this specification and the appended claims, the term “time-domain” refers to a process by which a single reactive gas is injected into the processing chamber at a time and purged before another reactive gas is injected. This prevents the gas-phase reaction of the reactive gases within the processing chamber and effectively limits the reactions to surface-based reactions. The processing chamber 100 may include a chamber body 101, a lid assembly 138, and a support assembly 120, also referred to as a substrate support. The lid assembly 138 is disposed at an upper end of the chamber body 101, and the support assembly 120 is at least partially disposed within the chamber body 101. The chamber body 101 may include a slit valve opening 111 formed in a sidewall thereof to provide access to the interior of the processing chamber 100. The slit valve opening 111 is selectively opened and closed to allow access to the interior of the chamber body 101 by a robot (not shown).

It will be understood by those skilled in the art that the descriptions of the components below may also be applicable for spatial ALD processing chambers. The chamber body 101 may include a channel 102 formed therein for flowing a heat transfer fluid therethrough. The heat transfer fluid can be a heating fluid or a coolant and is used to control the temperature of the chamber body 101 during processing and substrate transfer. Exemplary heat transfer fluids include water, ethylene glycol, or a mixture thereof. An exemplary heat transfer fluid may also include nitrogen gas.

The chamber body 101 can further include a liner 108 that surrounds the support assembly 120. The liner 108 is preferably removable for servicing and cleaning. The liner 108 can be made of a metal such as aluminum, or a ceramic material. However, the liner 108 can be any process compatible material. The liner 108 can be bead blasted to increase the adhesion of any material deposited thereon, thereby preventing flaking of material which results in contamination of the processing chamber 100. The liner 108 may include one or more apertures 109 and a pumping channel 106 formed therein that is in fluid communication with a vacuum system. The apertures 109 provide a flow path for gases into the pumping channel 106, which provides an egress for the gases within the processing chamber 100.

The vacuum system can include a vacuum pump 104 and a throttle valve 105 to regulate flow of gases through the processing chamber 100. The vacuum pump 104 is coupled to a vacuum port 107 disposed on the chamber body 101 and therefore is in fluid communication with the pumping channel 106 formed within the liner 108.

Apertures 109 allow the pumping channel 106 to be in fluid communication with a processing zone 112 within the chamber body 101. The processing zone 112 is defined by a lower surface of the lid assembly 138 and an upper surface of the support assembly 120, and is surrounded by the liner 108. The apertures 109 may be uniformly sized and evenly spaced about the liner 108. However, any number, position, size or shape of apertures may be used, and each of those design parameters can vary depending on the desired flow pattern of gas across the substrate receiving surface as is discussed in more detail below. In addition, the size, number and position of the apertures 109 are configured to achieve uniform flow of gases exiting the processing chamber 100. Further, the aperture size and location may be configured to provide rapid or high capacity pumping to facilitate a rapid exhaust of gas from the chamber 100. For example, the number and size of apertures 109 in close proximity to the vacuum port 107 may be smaller than the size of apertures 109 positioned farther away from the vacuum port 107.

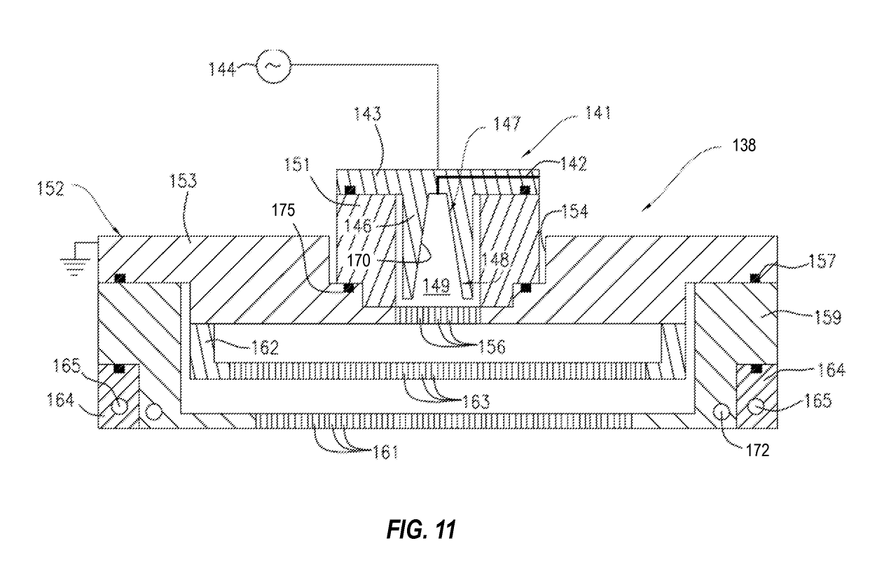

Considering the lid assembly 138 in more detail, FIG. 11 shows an enlarged cross sectional view of lid assembly 138 that may be disposed at an upper end of the chamber body 101. Referring to FIGS. 3 and 4, the lid assembly 138 includes a number of components stacked on top of one another to form a plasma region or cavity therebetween. The lid assembly 138 may include a first electrode 141 (“upper electrode”) disposed vertically above a second electrode 152 (“lower electrode”) confining a plasma volume or cavity 149 therebetween. The first electrode 141 is connected to a power source 144, such as an RF power supply, and the second electrode 152 is connected to ground, forming a capacitance between the two electrodes 141, 152.

The lid assembly 138 may include one or more gas inlets 142 (only one is shown) that are at least partially formed within an upper section 143 of the first electrode 141. One or more process gases enter the lid assembly 138 via the one or more gas inlets 142. The one or more gas inlets 142 are in fluid communication with the plasma cavity 149 at a first end thereof and coupled to one or more upstream gas sources and/or other gas delivery components, such as gas mixers, at a second end thereof. The first end of the one or more gas inlets 142 may open into the plasma cavity 149 at the upper-most point of the inner diameter 150 of expanding section 146. Similarly, the first end of the one or more gas inlets 142 may open into the plasma cavity 149 at any height interval along the inner diameter 150 of the expanding section 146. Although not shown, two gas inlets 142 can be disposed at opposite sides of the expanding section 146 to create a swirling flow pattern or “vortex” flow into the expanding section 146 which helps mix the gases within the plasma cavity 149.

The first electrode 141 may have an expanding section 146 that houses the plasma cavity 149. The expanding section 146 may be in fluid communication with the gas inlet 142 as described above. The expanding section 146 may be an annular member that has an inner surface or diameter 150 that gradually increases from an upper portion 147 thereof to a lower portion 148 thereof. As such, the distance between the first electrode 141 and the second electrode 152 is variable. That varying distance helps control the formation and stability of the plasma generated within the plasma cavity 149.

The expanding section 146 may resemble a cone or “funnel,” as is shown in FIGS. 10 and 11. The inner surface 170 of the expanding section 146 may gradually slope from the upper portion 147 to the lower portion 148 of the expanding section 146. The slope or angle of the inner diameter 150 can vary depending on process requirements and/or process limitations. The length or height of the expanding section 146 can also vary depending on specific process requirements and/or limitations. The slope of the inner diameter 150, or the height of the expanding section 146, or both may vary depending on the volume of plasma needed for processing.

Not wishing to be bound by theory, it is believed that the variation in distance between the two electrodes 141, 152 allows the plasma formed in the plasma cavity 149 to find the necessary power level to sustain itself within some portion of the plasma cavity 149, if not throughout the entire plasma cavity 149. The plasma within the plasma cavity 149 is therefore less dependent on pressure, allowing the plasma to be generated and sustained within a wider operating window. As such, a more repeatable and reliable plasma can be formed within the lid assembly 138.

The first electrode 141 can be constructed from any process compatible materials, such as aluminum, anodized aluminum, nickel plated aluminum, nickel plated aluminum 6061-T6, stainless steel as well as combinations and alloys thereof, for example. In one or more embodiments, the entire first electrode 141 or portions thereof are nickel coated to reduce unwanted particle formation. Preferably, at least the inner surface 170 of the expanding section 146 is nickel plated.

The second electrode 152 can include one or more stacked plates. When two or more plates are desired, the plates should be in electrical communication with one another. Each of the plates should include a plurality of apertures or gas passages to allow the one or more gases from the plasma cavity 149 to flow through.

The lid assembly 138 may further include an isolator ring 151 to electrically isolate the first electrode 141 from the second electrode 152. The isolator ring 151 can be made from aluminum oxide or any other insulative, process compatible material. Preferably, the isolator ring 151 surrounds or substantially surrounds at least the expanding section 146.

The second electrode 152 may include a top plate 153, distribution plate 158 and blocker plate 162 separating the substrate in the processing chamber from the plasma cavity. The top plate 153, distribution plate 158 and blocker plate 162 are stacked and disposed on a lid rim 164 which is connected to the chamber body 101 as shown in FIG. 3. As is known in the art, a hinge assembly (not shown) can be used to couple the lid rim 164 to the chamber body 101. The lid rim 164 can include an embedded channel or passage 165 for housing a heat transfer medium. The heat transfer medium can be used for heating, cooling, or both, depending on the process requirements.

The top plate 153 may include a plurality of gas passages or apertures 156 formed beneath the plasma cavity 149 to allow gas from the plasma cavity 149 to flow therethrough. The top plate 153 may include a recessed portion 154 that is adapted to house at least a portion of the first electrode 141 or a recessed portion 154 to house at least a portion of the first electrode. In one or more embodiments, the apertures 156 are through the cross section of the top plate 153 beneath the recessed portion 154. The recessed portion 154 of the top plate 153 can be stair stepped as shown in FIG. 11 to provide a better sealed fit therebetween. Furthermore, the outer diameter of the top plate 153 can be designed to mount or rest on an outer diameter of the distribution plate 158 as shown in FIG. 11. An o-ring type seal, such as an elastomeric o-ring 175, can be at least partially disposed within the recessed portion 154 of the top plate 153 to ensure a fluid-tight contact with the first electrode 141. Likewise, an o-ring type seal 157 can be used to provide a fluid-tight contact between the outer perimeters of the top plate 153 and the distribution plate 158.

The distribution plate 158 is substantially disc-shaped and includes a plurality of apertures 161 or passageways to distribute the flow of gases therethrough. The apertures 161 can be sized and positioned about the distribution plate 158 to provide a controlled and even flow distribution to the processing zone 112 where the substrate 60 to be processed is located. Furthermore, the apertures 161 prevent the gas(es) from impinging directly on the substrate 60 surface by slowing and re-directing the velocity profile of the flowing gases, as well as evenly distributing the flow of gas to provide an even distribution of gas across the surface of the substrate 60.

The distribution plate 158 can also include an annular mounting flange 159 formed at an outer perimeter thereof. The mounting flange 159 can be sized to rest on an upper surface of the lid rim 164. An o-ring type seal, such as an elastomeric o-ring, can be at least partially disposed within the annular mounting flange 159 to ensure a fluid-tight contact with the lid rim 164.

The distribution plate 158 may include one or more embedded channels or passages 172 for housing a heater or heating fluid to provide temperature control of the lid assembly 138. A resistive heating element can be inserted within the passage 172 to heat the distribution plate 158. A thermocouple can be connected to the distribution plate 158 to regulate the temperature thereof. The thermocouple can be used in a feedback loop to control electric current applied to the heating element, as known in the art.

Alternatively, a heat transfer medium can be passed through the passage 172. The one or more passages 172 can contain a cooling medium, if needed, to better control temperature of the distribution plate 158 depending on the process requirements within the chamber body 101. As mentioned above, any heat transfer medium may be used, such as nitrogen, water, ethylene glycol, or mixtures thereof, for example.

The lid assembly 138 may be heated using one or more heat lamps (not shown). Typically, the heat lamps are arranged about an upper surface of the distribution plate 158 to heat the components of the lid assembly 138 including the distribution plate 158 by radiation.

The blocker plate 162 is optional and may be disposed between the top plate 153 and the distribution plate 158. Preferably, the blocker plate 162 is removably mounted to a lower surface of the top plate 153. The blocker plate 162 should make good thermal and electrical contact with the top plate 153. The blocker plate 162 may be coupled to the top plate 153 using a bolt or similar fastener. The blocker plate 162 may also be threaded or screwed onto an out diameter of the top plate 153.

The blocker plate 162 includes a plurality of apertures 163 to provide a plurality of gas passages from the top plate 153 to the distribution plate 158. The apertures 163 can be sized and positioned about the blocker plate 162 to provide a controlled and even flow distribution the distribution plate 158.

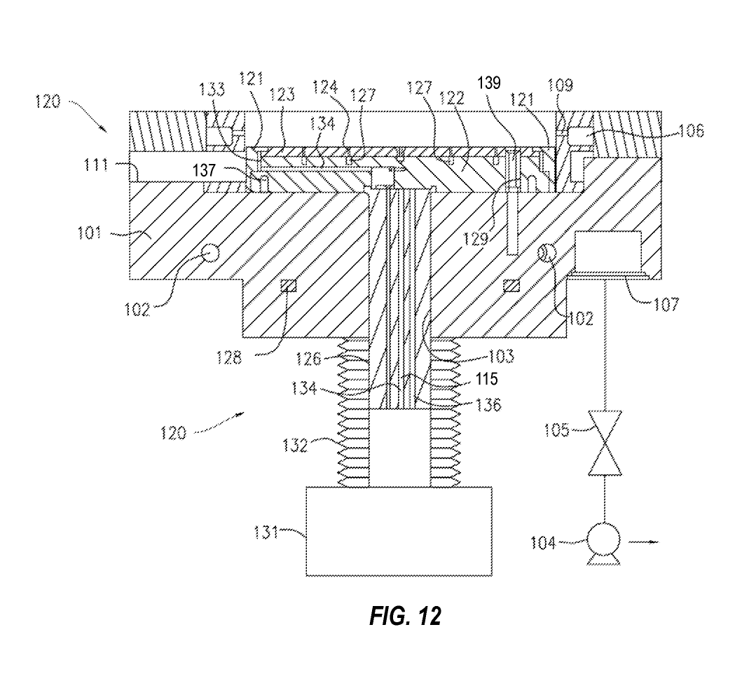

FIG. 12 shows a partial cross sectional view of an illustrative support assembly 120 or substrate support. The support assembly 120 can be at least partially disposed within the chamber body 101. The support assembly 120 can include a support member 122 to support the substrate 60 (not shown in this view) for processing within the chamber body 101. The support member 122 can be coupled to a lift mechanism 131 through a shaft 126 which extends through a centrally-located opening 103 formed in a bottom surface of the chamber body 101. The lift mechanism 131 can be flexibly sealed to the chamber body 101 by a bellows 132 that prevents vacuum leakage from around the shaft 126. The lift mechanism 131 allows the support member 122 to be moved vertically within the chamber body 101 between a process position and a lower, transfer position. The transfer position is slightly below the opening of the slit valve 111 formed in a sidewall of the chamber body 101.

In one or more embodiments, the substrate 60 (not shown in FIG. 12) may be secured to the support assembly 120 using a vacuum chuck. The top plate 123 can include a plurality of holes 124 in fluid communication with one or more grooves 127 formed in the support member 122. The grooves 127 are in fluid communication with a vacuum pump (not shown) via a vacuum conduit 115 disposed within the shaft 126 and the support member 122. Under certain conditions, the vacuum conduit 115 can be used to supply a purge gas to the surface of the support member 122 when the substrate 60 is not disposed on the support member 122. The vacuum conduit 115 can also pass a purge gas during processing to prevent a reactive gas or byproduct from contacting the backside of the substrate 60.

The support member 122 can include one or more bores 129 formed therethrough to accommodate a lift pin 139. Each lift pin 139 is typically constructed of ceramic or ceramic-containing materials, and are used for substrate-handling and transport. Each lift pin 139 is slideably mounted within the bore 129. The lift pin 139 is moveable within its respective bore 129 by engaging an annular lift ring 128 disposed within the chamber body 101. The lift ring 128 is movable such that the upper surface of the lift-pin 139 can be located above the substrate support surface of the support member 122 when the lift ring 128 is in an upper position. Conversely, the upper surface of the lift-pins 139 is located below the substrate support surface of the support member 122 when the lift ring 128 is in a lower position. Thus, part of each lift-pin 139 passes through its respective bore 129 in the support member 122 when the lift ring 128 moves from either the lower position to the upper position.

When activated, the lift pins 139 push against a lower surface of the substrate 60, lifting the substrate 60 off the support member 122. Conversely, the lift pins 139 may be de-activated to lower the substrate 60, thereby resting the substrate 60 on the support member 122.

The support assembly 120 can include an edge ring 121 disposed about the support member 122. The edge ring 121 is an annular member to cover an outer perimeter of the support member 122 and protect the support member 122. The edge ring 121 can be positioned on or adjacent the support member 122 to form an annular purge gas channel 133 between the outer diameter of support member 122 and the inner diameter of the edge ring 121. The annular purge gas channel 133 can be in fluid communication with a purge gas conduit 134 formed through the support member 122 and the shaft 126. Preferably, the purge gas conduit 134 is in fluid communication with a purge gas supply (not shown) to provide a purge gas to the purge gas channel 133. In operation, the purge gas flows through the conduit 134, into the purge gas channel 133, and about an edge of the substrate disposed on the support member 122. Accordingly, the purge gas working in cooperation with the edge ring 121 prevents deposition at the edge and/or backside of the substrate.

The temperature of the support assembly 120 is controlled by a fluid circulated through a fluid channel 137 embedded in the body of the support member 122. The fluid channel 137 may be in fluid communication with a heat transfer conduit 136 disposed through the shaft 126 of the support assembly 120. The fluid channel 137 may be positioned about the support member 122 to provide a uniform heat transfer to the substrate receiving surface of the support member 122. The fluid channel 137 and heat transfer conduit 136 can flow heat transfer fluids to either heat or cool the support member 122. The support assembly 120 can further include an embedded thermocouple (not shown) for monitoring the temperature of the support surface of the support member 122.

In operation, the support member 122 can be elevated to a close proximity of the lid assembly 138 to control the temperature of the substrate 60 being processed. As such, the substrate 60 can be heated via radiation emitted from the distribution plate 158 that is controlled by the heating element 474. Alternatively, the substrate 60 can be lifted off the support member 122 to close proximity of the heated lid assembly 138 using the lift pins 139 activated by the lift ring 128.

In some embodiments, one or more layers may be formed during a plasma enhanced atomic layer deposition (PEALD) process. In some processes, the use of plasma provides sufficient energy to promote a species into the excited state where surface reactions become favorable and likely. Introducing the plasma into the process can be continuous or pulsed. In some embodiments, sequential pulses of precursors (or reactive gases) and plasma are used to process a layer. In some embodiments, the reagents may be ionized either locally (i.e., within the processing area) or remotely (i.e., outside the processing area). In some embodiments, remote ionization can occur upstream of the deposition chamber such that ions or other energetic or light emitting species are not in direct contact with the depositing film. In some PEALD processes, the plasma is generated external from the processing chamber, such as by a remote plasma generator system. The plasma may be generated via any suitable plasma generation process or technique known to those skilled in the art. For example, plasma may be generated by one or more of a microwave (MW) frequency generator or a radio frequency (RF) generator. The frequency of the plasma may be tuned depending on the specific reactive species being used. Suitable frequencies include, but are not limited to, 2 MHz, 13.56 MHz, 40 MHz, 60 MHz and 100 MHz. Although plasmas may be used during the deposition processes disclosed herein, it should be noted that plasmas may not required. Indeed, other embodiments relate to deposition processes under very mild conditions without a plasma.

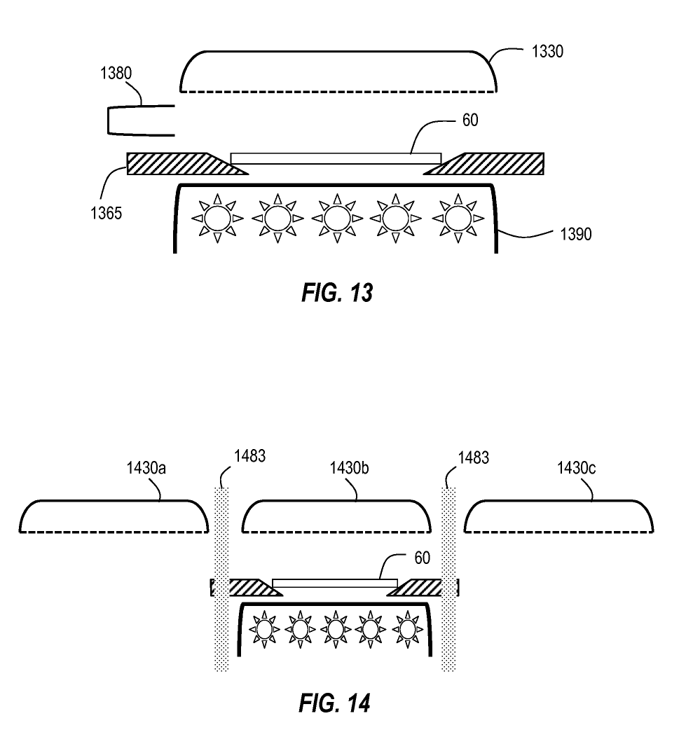

FIG. 13 shows a schematic representation of an atomic layer deposition chamber in accordance with one or more embodiments of the invention. In the embodiment shown, the substrate 60 rests on a wafer support ring 1365 beneath a showerhead 1330. An injection port 1380 is positioned in the side of the processing chamber to provide a flow of precursor from a different path than the showerhead 1330 so that incompatible precursors can be delivered to the chamber from different paths. An exhaust port can also be position within the processing chamber to exhaust the gases from the processing chamber. A rapid thermal lamphead 1390 is positioned beneath the substrate 60. A typical process cycle could be: exposure to precursors, purge, heat treatment, purge; or exposure to precursor 1, purge, precursor 2, purge, heat treatment, purge; or precursor 1, purge, heat treatment, purge, precursor 2, purge, heat treatment, purge; wherein the purge steps are optional.

FIG. 14 shows a schematic representation of a deposition chamber in accordance with one or more embodiments of the invention. In the embodiment shown, the substrate moves from a first precursor zone 1430a through a zone of differential pumping 1483 (e.g., an air curtain or purge) to a precursor zone 1430b with heat treatment through another zone of differential pumping 1483 to an optional second precursor zone 1430c. The heat treatment can be done with an RTP lamp head or a line heated source such as a focused laser line to heat treat in scanning mode, a line shape lamp or a microwave heated area. Moving speed and laser power will determine the thermal budget. The wafer on the support moves back and forth between the zones to realize the ALD cycles. Outside the heated zone, the wafer is exposed to precursors. A proper air curtain and differential pumping could be inserted to ensure zone isolation and purge pose exposure/treatment.

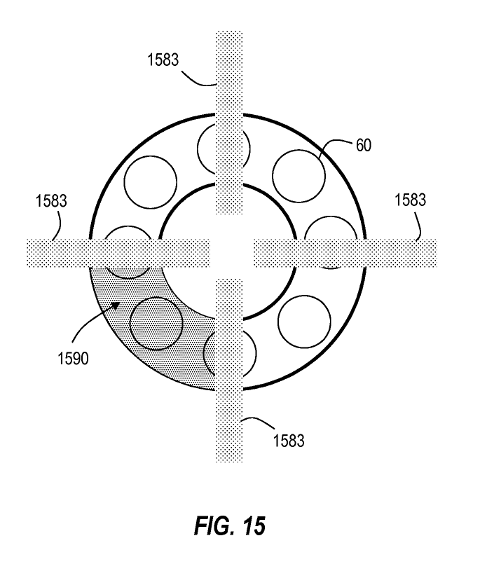

FIG. 15 shows a schematic representation of a deposition chamber in accordance with another embodiment of the invention. In the embodiment shown, substrates 60 move in a circular path or a circular tunnel that is sectioned into multiple zones for precursors, purge and heat treatments. Multiple wafers can be processed as mini-batches and can pass the zones in a continuous circular motion to realize single wafer mini-batch processes. Every zone can be pumping to a central exhaust to evacuate unreacted gases. Each section of the path can be separated by air curtains 1583, or similar. The embodiment shown has a quarter of the circular path for heat treatment with a suitable heat treatment device 1590.

According to one or more embodiments, the substrate is subjected to processing prior to and/or after forming the layer. This processing can be performed in the same chamber or in one or more separate processing chambers. In some embodiments, the substrate is moved from the first chamber to a separate, second chamber for further processing. The substrate can be moved directly from the first chamber to the separate processing chamber, or it can be moved from the first chamber to one or more transfer chambers, and then moved to the desired separate processing chamber. Accordingly, the processing apparatus may comprise multiple chambers in communication with a transfer station. An apparatus of this sort may be referred to as a “cluster tool” or “clustered system”, and the like.

Generally, a cluster tool is a modular system comprising multiple chambers which perform various functions including substrate center-finding and orientation, degassing, annealing, deposition and/or etching. According to one or more embodiments, a cluster tool includes at least a first chamber and a central transfer chamber. The central transfer chamber may house a robot that can shuttle substrates between and among processing chambers and load lock chambers. The transfer chamber is typically maintained at a vacuum condition and provides an intermediate stage for shuttling substrates from one chamber to another and/or to a load lock chamber positioned at a front end of the cluster tool. Two well-known cluster tools which may be adapted for the present invention are the Centura® and the Endura®, both available from Applied Materials, Inc., of Santa Clara, Calif. The details of one such staged-vacuum substrate processing apparatus is disclosed in U.S. Pat. No. 5,186,718, entitled “Staged-Vacuum Wafer Processing Apparatus and Method,” Tepman et al., issued on Feb. 16, 1993. However, the exact arrangement and combination of chambers may be altered for purposes of performing specific steps of a process as described herein. Other processing chambers which may be used include, but are not limited to, cyclical layer deposition (CLD), atomic layer deposition (ALD), chemical vapor deposition (CVD), physical vapor deposition (PVD), etch, pre-clean, chemical clean, thermal treatment such as RTP, plasma nitridation, degas, orientation, hydroxylation and other substrate processes. By carrying out processes in a chamber on a cluster tool, surface contamination of the substrate with atmospheric impurities can be avoided without oxidation prior to depositing a subsequent film.

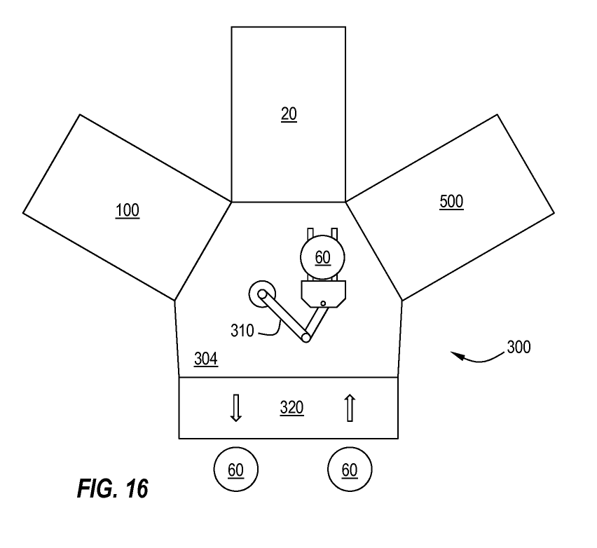

Referring to FIG. 16, an illustrative cluster tool 300 includes a central transfer chamber 304 generally including a multi-substrate robot 310 adapted to transfer a plurality of substrates in and out of the load lock chamber 320 and the various processing chambers. Although the cluster tool 300 is shown with processing chambers 20 which may be, for example, a spatial ALD processing chamber, processing chamber 100, which may be, for example, a time-domain ALD processing chamber and a third processing chamber 500, for example, a rapid thermal processing chamber, it will be understood by those skilled in the art that there can be more or less than 3 processing chambers. Additionally, the processing chambers can be for different types (e.g., ALD, CVD, PVD) of substrate processing techniques.

According to one or more embodiments, the substrate is continuously under vacuum or “load lock” conditions, and is not exposed to ambient air when being moved from one chamber to the next. The transfer chambers are thus under vacuum and are “pumped down” under vacuum pressure. Inert gases may be present in the processing chambers or the transfer chambers. In some embodiments, an inert gas is used as a purge gas to remove some or all of the reactants after forming the silicon layer on the surface of the substrate. According to one or more embodiments, a purge gas is injected at the exit of the deposition chamber to prevent reactants from moving from the deposition chamber to the transfer chamber and/or additional processing chamber. Thus, the flow of inert gas forms a curtain at the exit of the chamber.

The substrate can be processed in single substrate deposition chambers, where a single substrate is loaded, processed and unloaded before another substrate is processed. The substrate can also be processed in a continuous manner, like a conveyer system, in which multiple substrate are individually loaded into a first part of the chamber, move through the chamber and are unloaded from a second part of the chamber. The shape of the chamber and associated conveyer system can form a straight path or curved path. Additionally, the processing chamber may be a carousel in which multiple substrates are moved about a central axis and are exposed to deposition, etch, annealing, cleaning, etc. processes throughout the carousel path.

During processing, the substrate can be heated or cooled. Such heating or cooling can be accomplished by any suitable means including, but not limited to, changing the temperature of the substrate support and flowing heated or cooled gases to the substrate surface. In some embodiments, the substrate support includes a heater/cooler which can be controlled to change the substrate temperature conductively. In one or more embodiments, the gases (either reactive gases or inert gases) being employed are heated or cooled to locally change the substrate temperature. In some embodiments, a heater/cooler is positioned within the chamber adjacent the substrate surface to convectively change the substrate temperature.

The substrate can also be stationary or rotated during processing. A rotating substrate can be rotated continuously or in discrete steps. For example, a substrate may be rotated throughout the entire process, or the substrate can be rotated by a small amount between exposure to different reactive or purge gases. Rotating the substrate during processing (either continuously or in steps) may help produce a more uniform deposition or etch by minimizing the effect of, for example, local variability in gas flow geometries.

One or more embodiments of the invention are directed to methods of forming a film on a substrate, or a portion of a substrate. As used in this specification and the appended claims, and as will be understood by those skilled in the art, reference to a substrate surface does not necessarily mean the entire substrate surface, but can be a limited area or a portion of the substrate. The substrate is exposed to a first reactive gas at a first temperature. At the first temperature, the first reactive gaseous species are absorbed onto the surface of the substrate. The absorbed species can form a film or be simply absorbed molecules. The temperature of the absorbed reactive gas is then rapidly elevated from the first temperature to a second temperature which is greater than the first temperature. The rapid elevation of temperature can result in the transformation of the absorbed species. For example, if the absorbed species is simply absorbed molecules, rapidly heating can cause these absorbed molecules to directly form an epitaxial film. If the absorbed species is a film, rapidly heating the film can cause the properties of the film to change (e.g., conversion of an amorphous film to an epitaxial film).

In some embodiments, the absorbed reactive gaseous species are exposed to a second reactive gas which is different from the first reactive gas. The second reactive gas can form a film on the substrate separately from the first reactive species or in combination with the first reactive species or can simply be absorbed molecules. Again, rapidly heating can cause a transformation in the absorbed species. For example, rapid heating can cause one or more of promoting a chemical reaction between the first absorbed species and the second absorbed species to create a film (e.g., a high-k dielectric film or an epitaxial film) or can cause conversion of the film to have different properties as in converting an amorphous film to an epitaxial film.

In some embodiments, the substrate and/or the first absorbed species is exposed to the second reactive gas before rapidly raising temperature of the absorbed reactive gas. In one or more embodiments, the substrate and/or the first absorbed species is exposed to the second reactive gas after rapidly raising the temperature of the absorbed reactive gas. The temperature of the absorbed species and/or films formed can be rapidly raised again after exposure to the second reactive gas.

In some embodiments, the low temperature enables the selective absorption of the first reactive species and/or the second reactive species to a first portion of the substrate over a second portion of the substrate. For example, a substrate with a film thereon forming features and trenches through the features exposing the substrate surface is commonly encountered in semiconductor processing. The film on the substrate can be any suitable film including, but not limited to, high-k dielectrics, dielectrics and metal layers. Depositing a film over such a device is complicated by the fact that a film can be formed on both the top of the features and the bottom of the trenches. Exposing the substrate with features thereon to the first reactive species at low temperature can result in the selective absorption of the first reactive species to one of the features or the trench bottoms over the other. Then rapid raising of the temperature results in the conversion of the absorbed reactive species to a film (e.g., a dielectric film or an epitaxial film). Since ALD reactions are self-limiting, a first reactive gas can be selectively absorbed onto the features or the bottom of the trenches. Then, rapidly heating the absorbed first reactive gas can activate the absorbed species for further reaction with a second reactive gas. In this case, the second reactive gas may react with activated absorbed species and not with the portions of the substrate without the first reactive species absorbed thereon.

In some embodiments, the substrate surface, or a portion of the substrate surface, is exposed to the first reactive gas and the second reactive gas prior to rapid heating. The substrate can exposed to both the first reactive gas and the second reactive gas at the same time or separately. If the first temperature is below a temperature where the first reactive gas would react with the second reactive gas, then both gases can be flowed together to the processing chamber, or can be flowed simultaneously, but through different conduits, to the processing chamber.

The low temperature exposure to the first and/or second reactive gases can result in the selective absorption of the gas to the substrate or a portion of the substrate. This allows for the formation of a mixed film on the substrate, or portion of the substrate, For example, both the first reactive gas and the second reactive gas can be absorbed to the substrate, or portion of the substrate. Then, rapid heating can cause the film to be formed as a mixed film of the first reactive species and the second reactive species, or can cause the first reactive species to react with the second reactive species on the substrate surface, or portion of the surface. In some embodiments, the first reactive gas is selective for a first portion of the substrate and the second reactive gas is selective for a second portion of the substrate. Thus, rapid heating can result in the formation of two films at the same time on different parts of the substrate (e.g., trenches or features). Each of the films can be a different type of film (e.g., dielectric, high-k dielectric, metal and epitaxial).

One or more embodiments of the invention are directed to methods of forming an epitaxial film on a substrate. The substrate is exposed to a first reactive gas to form an amorphous film on the surface of the substrate. As used in this specification and the appended claims, the term “reactive gas” is used interchangeably with “precursor” and means a gas that includes a species which is reactive in an atomic layer deposition process. The amorphous film is formed at a first temperature which is any suitable temperature for ALD reaction forming an amorphous film. As used in this specification and the appended claims, the terms “amorphous” and “substantially amorphous” are used interchangeably and mean that the film is at least about 90% amorphous, or at least about 95% amorphous or at least about 99% amorphous. Those skilled in the art understand that a small amount of the film formed at low temperature may be epitaxial in that the crystal structure in isolated regions may be conformal to the crystal structure of the substrate. In addition, the general process described can be used to directly grow an epitaxial film without passing through an amorphous phase. For example, the reactive gases can activated by the heat treatment to directly from the epitaxial film. An epitaxial film could be grown by absorbing a precursor on the surface, pump out left over gas, then heat treat the film. This process may advantageously use low temperatures to realize selective absorption of the precursor and, therefore, selective epi growth.

In some embodiments, only a single reactive gas is needed to form the amorphous film on the substrate surface. In embodiments of this sort, the film formation is self-limiting in that once the entire available surface of the substrate is reacted with the reactive gas species. However, the single reactive gas forms a film which is substantially amorphous.

The temperature of the amorphous film is rapidly raised to a second temperature which is greater than the first temperature. Rapidly raising the temperature causes the substantially amorphous film to convert to a substantially epitaxial film. As used in this specification and the appended claims, the terms “epitaxial” and “substantially epitaxial” are used interchangeably to mean that the film is greater than about 90% epitaxial, or greater than about 95% epitaxial or greater than about 99% epitaxial. As used in this specification and the appended claims, the term “rapidly” means that the temperature is raised at a rate greater than about 50° C./sec. In some embodiments, the temperature is raised at a rate greater than about 100° C./sec, or greater than about 150° C./sec, or greater than about 200° C./sec, or greater than about 250° C./sec, or greater than about 300° C./sec or greater than about 350° C./sec. In one or more embodiments, the temperature is raised at a rate in the range of about 50° C./sec to about 400° C./sec. In some embodiments, for example when laser annealing is used, the ramp rate can be extremely high. A laser annealing process can have a ramp rate in the millions of degrees per second. In one or more embodiments, the ramp rate is in the range of about 50° C./sec to about 2 million° C./sec.

In some embodiments, the substantially amorphous film is formed as the result of reactions of a first reactive gas with the substrate followed by a second reactive gas with the first reactive gas on the substrate. The second reactive gas being different from the first reactive gas. Two part reactions of this type are often used in atomic layer deposition to form the final film. Here, however, the film formed is substantially amorphous. The substrate can be exposed to the second reactive gas at the same temperature as the first reactive gas or at a different temperature. The temperature may have a marked impact on the extent of the surface reactions of the gaseous species. For example, if the temperature is too low, the reaction may not take place at all. If the temperature is too high, the reaction efficiency may be destroyed or the reaction may no longer be the energetically most favorable outcome.

In some embodiments, the substrate is exposed to the second reactive gas after removing the first reactive gas from the processing chamber. This minimizes the likelihood of gas phase reactions between the first and second reactive gases to maximize reactions on the substrate surface.

In one or more embodiments, the first reactive gas and the second reactive gas are exposed to the substrate at the same time. This allows reactions on the surface of the substrate by individual reactants as well as gas phase reaction of the reactive gases which can then react with the substrate surface. Exposing the substrate to both gases simultaneously can occur as mixed gases like in a CVD type reaction or separate and isolated simultaneous gas flows like that in a spatial ALD type process, as described above. In some embodiments, the substrate is exposed to both the first reactive gas and the second reactive gas at the same time, with each of the first reactive gas and the second reactive gas being delivered to the substrate surface separately and removed from the substrate surface without mixing.

In one or more embodiments, the substrate is exposed to the second reactive gas after removing the first reactive gas. For example, a conventional ALD reaction where the first reactive gas is exposed to the substrate, purged from the system, and the second reactive gas is exposed to the substrate and purged from the system.

The reaction temperatures can be modified depending on the specific reagents being used. Each reaction has conditions that are most favorable for the film formation process. In some embodiments, the first temperature is up to about 400° C. The first reactive gas and the second reactive gas, when delivered separately, can be at the same temperature of different temperatures. If the second reactive gas is at a different temperature than the first reactive gas, to distinguish temperatures of the various reactions, it can be said that the second reactive gas is at a third temperature. When at different temperatures, both the temperature of the first reactive gas reaction and the second reactive gas reaction may be less than about 400° C. In some embodiments, the first temperature is in the range of about 50° C. to about 400° C., or in the range of about 100° C. to about 300° C.

The second temperature, which is the temperature used to convert the substantially amorphous film to the substantially epitaxial film, is also dependent on the specific film being formed. Some materials will require higher or lower second temperatures for epitaxial film formation. In one or more embodiments, the second temperature is greater than about 600° C. In some embodiments, the second temperature is in the range of about 600° C. to about 1600° C., or the second temperature is in the range of about 600° C. to about 1300° C., or in the range of about 700° C. to about 1200° C.

The rate at which the temperature is increased to the second temperature is rapid to form the epitaxial film as well as preserve as much of the thermal budget as possible. Accordingly, the length of time that it takes to reach the second temperature will depend on the rate of increasing the temperature and the temperature difference between the first temperature and the second temperature, or between the third temperature and the second temperature. In some embodiments, rapidly raising the temperature of the amorphous film occurs over a time period up to about 60 seconds.

The amount of time that the film is held at the second temperature also affects the thermal budget and film quality. In some embodiments, the film is held at the second temperature for a time in the range of about 0.1 sec to about 60 seconds. In some embodiments, the exposure time can be in the nanosecond scale depending on the temperature and technology used. For short time, the temperature could be as high as 1500° C.

The specific film formation process can vary. In some embodiments, the amorphous film formed is up to about one monolayer thick before rapidly raising the temperature to form the epitaxial film. In one or more embodiments, the amorphous film formed is up to five monolayers thick before rapid thermal processing. Some reactions can result in less than a full monolayer being formed on the substrate because the reaction processes have not self-saturated before stopping the reaction. For example, referring to FIG. 3, the substrate can be passed under the gas distribution plate so that a film at least a partial monolayer thick is formed. The substrate is then moved to the rapid thermal processing device where the film is converted to epitaxial. The process can be repeated any number of times to that an amorphous film is deposited and converted to epitaxial repeatedly to build the thickness of the epitaxial film. Stated differently, the process can sequentially form an amorphous film on the epitaxial film, the amorphous film having a thickness up to about one monolayer thick, followed by rapidly raising the temperature of the amorphous film to form the epitaxial film.

The rapid thermal processing device can be any suitable device for rapidly raising the temperature of the film in a controlled manner. In some embodiments, the temperature of the amorphous film is rapidly raised by one or more of IR lamps, UV lamps, lasers, RF, microwave and exposure to plasma.

In some embodiments, additional processing is performed one or more of before and after the formation of the epitaxial film on the substrate without exposing the substrate to the ambient environment. For example, cleaning processes, polishing processes, additional film deposition, etching and annealing.

Additional embodiments of the invention are directed to methods of forming an epitaxial film on a substrate. A substantially amorphous film is formed on the surface of the substrate by atomic layer deposition. The substantially amorphous film is formed at a first temperature. The temperature of the substantially amorphous film is rapidly raised from the first temperature to a second temperature to convert the substantially amorphous film to a substantially epitaxial film.

In one or more embodiments, forming the substantially amorphous film comprising exposing the surface of the substrate to a first reactive gas followed by a second reactive gas. It will be understood by those skilled in the art that the surface of the substrate does not need to be a bare substrate surface, but can also include a film already formed on the substrate.

Further embodiments of the invention are directed to methods of forming an epitaxial film on a substrate surface. The substrate is positioned on a substrate support. The substrate support is moved laterally while holding the substrate beneath a gas distribution plate comprising a plurality of elongate gas ports, as shown in FIG. 1. The elongate gas ports include a first out A to deliver a first reactive gas and a second outlet B to deliver a second reactive gas. The first reactive gas is delivered to the substrate surface, or a film on the substrate surface. The second reactive gas is delivered to the substrate surface, or the film on the substrate surface (e.g., the film formed by the first reactive gas) to form a substantially amorphous film on the substrate surface. The local temperature of at least a portion of the substantially amorphous film is rapidly changed to convert the substantially amorphous film to a substantially epitaxial film.

Although the invention herein has been described with reference to particular embodiments, it is to be understood that these embodiments are merely illustrative of the principles and applications of the present invention. It will be apparent to those skilled in the art that various modifications and variations can be made to the method and apparatus of the present invention without departing from the spirit and scope of the invention. Thus, it is intended that the present invention include modifications and variations that are within the scope of the appended claims and their equivalents.

What is claimed is:

1. A method of forming a film on a substrate, the method comprising:
exposing the substrate to a first reactive gas at a first temperature to absorb the first reactive gas to the substrate; and
rapidly raising temperature of the absorbed reactive gas to a second temperature greater than the first temperature to form a film.

2. The method of claim 1, further comprising exposing the absorbed reactive gas on the substrate to a second reactive gas different from the first reactive gas.

3. The method of claim 2, wherein the substrate is exposed to the second reactive gas before rapidly raising temperature of the absorbed reactive gas.

4. The method of claim 2, wherein the substrate is exposed to the second reactive gas after rapidly raising temperature of the absorbed reactive gas.

5. The method of claim 1, wherein the first temperature is up to about 400° C. and the second temperature is greater than about 600° C.

6. The method of claim 1, wherein the first reactive gas is selectively absorbed onto a first portion of the substrate at the first temperature over a second portion of the substrate.

7. The method of claim 1, wherein the film formed is an epitaxial film.

8. A method of forming an epitaxial film on a substrate, the method comprising:
exposing the substrate at a first temperature to a first reactive gas to form an amorphous film on a surface of the substrate; and
rapidly raising temperature of the amorphous film to a second temperature greater than the first temperature to form an epitaxial film.

9. The method of claim 8, wherein the temperature of the amorphous film is raised at a rate greater than about 50° C./sec.

10. The method of claim 8, further comprising exposing the substrate to a second reactive gas different from the first reactive gas to form the amorphous film.

11. The method of claim 10, wherein the substrate is exposed to the second reactive gas after removing the first reactive gas.

12. The method of claim 10, wherein the substrate is exposed to the second reactive gas at the same time as the first reactive gas.

13. The method of claim 10, wherein the substrate is exposed to both the first reactive gas and the second reactive gas at the same time, each of the first reactive gas and the second reactive gas being delivered to the substrate surface separately and removed from the substrate surface without mixing.

14. The method of claim 8, wherein rapidly raising the temperature of the amorphous film occurs over a time period up to about 60 seconds.

15. The method of claim 8, wherein the amorphous film formed is up to about one monolayer thick before rapidly raising the temperature to form the epitaxial film.

16. The method of claim 15, further comprising sequentially forming an amorphous film on the epitaxial film, the amorphous film having a thickness up to about one monolayer thick, followed by rapidly raising the temperature to form the epitaxial film.

17. The method of claim 10, wherein exposure to the first precursor followed by the second precursor results in one amorphous film up to about one monolayer thick before rapidly raising the temperature to form the epitaxial film.

18. The method of claim 8, wherein the temperature of the amorphous film is rapidly raised by one or more of UV lamps, lasers and exposure to plasma.

19. The method of claim 8, wherein the first reactive gas is selectively absorbed onto a first portion of the substrate at the first temperature over a second portion of the substrate.

20. A method of forming an epitaxial film on a substrate surface, the method comprising:
positioning the substrate on a substrate support;
laterally moving the substrate support holding the substrate beneath a gas distribution plate comprising a plurality of elongate gas ports including a first outlet A to deliver a first reactive gas and a second outlet B to deliver a second reactive gas;
delivering the first reactive gas to the substrate surface;
delivering the second reactive gas to the substrate surface to form an amorphous film on the substrate surface; and
rapidly changing the local temperature of at least a portion of the amorphous film to convert the amorphous film to an epitaxial film.
